(19) United States
(12) Patent Application Publication
(10) Pub. No.: US 2012/0056638 A1
(43) Pub. Date: Mar. 8, 2012

(54) SYSTEMS AND METHODS FOR MONITORING AND DIAGNOSTICS OF PHOTOVOLTAIC SOLAR MODULES IN PHOTOVOLTAIC SYSTEMS

(75) Inventor: Anders Swahn, Tiburon, CA (US)

(73) Assignee: Alion, Inc., Richmond, CA (US)

(21) Appl. No.: 13/043,286

(22) Filed: Mar. 8, 2011

Related U.S. Application Data
(60) Provisional application No. 61/312,523, filed on Mar. 10, 2010.

(51) Int. Cl. G01R 31/26

(52) U.S. Cl. 324/761.01

(57) ABSTRACT

A method and system for monitoring a photovoltaic module. The method includes initiating a monitoring process for a photovoltaic module at a predetermined time. The photovoltaic module is connected to at least another module in a photovoltaic string as a part of a photovoltaic array. Additionally, the method includes measuring one or more parameters of the photovoltaic module by a monitoring circuit. The one or more parameters include a module current flowing through the photovoltaic module, a module voltage across the photovoltaic module, and a module temperature of the photovoltaic module. Also, the method includes collecting one or more measurement results of the one or more parameters, transmitting the one or more collected results using one or more radio-frequency signals, and processing information associated with the one or more transmitted results.

### 1. CROSS-REFERENCES TO RELATED APPLICATIONS

This application claims priority to U.S. Provisional No. 61/312,523, filed Mar. 10, 2010, commonly assigned and incorporated by reference herein for all purposes.

### 2. BACKGROUND OF THE INVENTION

The present invention is directed to monitoring and diagnostics. More particularly, the invention provides systems and methods for monitoring and diagnostics of photovoltaic modules. Merely by way of example, the invention has been applied to photovoltaic systems. But it would be recognized that the invention has a much broader range of applicability.

Photovoltaics convert sunlight into electricity, providing a desirable source of clean energy. FIG. 1A is a simplified diagram of a conventional photovoltaic array. The photovoltaic array 100 includes strings 1, 2, 3, 4, . . . n, where n is a positive integer larger than or equal to 1. Each string includes photovoltaic (PV) modules (e.g., solar panels) that are connected in series. The photovoltaic array 100 is connected to a central inverter 110, which provides an alternating current (AC) connection to the power grid. FIG. 1B is a simplified diagram of a conventional photovoltaic module. The photovoltaic (PV) module 120 includes a junction box 130 on the backside of the PV module 120.

Performance of photovoltaic (PV) modules (e.g., solar panels) often degrades over time. If the performance of a photovoltaic module degrades significantly, other modules that are connected in series with the degraded module (e.g., in a string of solar panels) might end up not operating at the optimal power point (e.g., the Pₘₐₓ point on the current-voltage curve). Additionally, the performance of photovoltaic modules can degrade if their surface areas are covered by accumulated dirt. It is also possible that one or more photovoltaic modules display catastrophic failures. For example, a single degraded, or completely faulty, photovoltaic module can have an adverse effect on the power production of other well-functioning modules (e.g., other solar panels in the string).

Therefore, it is often useful to test the performance of individual photovoltaic (PV) modules. Such test can be performed with a specialized IV-tester when the PV modules are manufactured. But after the modules are installed in the field (e.g., as parts of a photovoltaic array), it can be cumbersome to disconnect the modules and perform such a test on individual modules. Furthermore, disconnecting one or more modules from a PV string under high voltage conditions may be dangerous and can also interrupt the power production.

FIG. 2 is a simplified conventional current-voltage (IV) curve of a photovoltaic module. As shown, one degraded photovoltaic module (e.g., a solar panel) in a PV string can force all other modules in the string to operate at a non-optimal power point, which is different from the optimal power point of Pₘₐₓ. Hence, it would be beneficial to be able to diagnose individually each module when the module is still connected in a PV string.

So far, the conventional technologies for monitoring individual PV modules often are expensive and power consuming. For example, one conventional diagnostic method places a voltage sensing circuitry, typically a printed circuit board, on top of a junction box in a specially designed enclosure. The circuitry transmits information about the PV module via cables or a wireless “WiFi” data interface to a central data collection unit. The problem with this approach is that the cost of such a wireless unit is considerable and the power consumed by the wireless unit is also significant. Additionally, the amount of information that needs to be conveyed is low, so the use of high-bandwidth wireless technology may be an overkill solution for the problems at hand. Hence this conventional technology is very expensive both from a monetary as well as power consumption point of view.

Another conventional diagnostic method monitors the performance of a PV string from a central inverter of a string aggregation terminal/box. However, the drawback with this method is that once it is discovered that there is an issue with a particular string, there is usually no way of knowing which, or which ones, of the PV modules in that string have a problem.

Hence it is highly desirable to improve diagnostic and monitoring techniques for photovoltaic modules.

### 3. BRIEF SUMMARY OF THE INVENTION

The present invention is directed to monitoring and diagnostics. More particularly, the invention provides systems and methods for monitoring and diagnostics of photovoltaic modules. Merely by way of example, the invention has been applied to photovoltaic systems. But it would be recognized that the invention has a much broader range of applicability.

According to one embodiment, a method for monitoring a photovoltaic module includes initiating a monitoring process for a photovoltaic module at a predetermined time. The photovoltaic module is connected to at least another module in a photovoltaic string as a part of a photovoltaic array. Additionally, the method includes measuring one or more parameters of the photovoltaic module by a monitoring circuit. The one or more parameters include a module current flowing through the photovoltaic module, a module voltage across the photovoltaic module, and a module temperature of the photovoltaic module. Also, the method includes collecting one or more measurement results of the one or more parameters, transmitting the one or more collected results using one or more radio-frequency signals, processing information associated with the one or more transmitted results, determining a module status for the photovoltaic module based on at least information associated with the one or more transmitted results, and making one or more adjustments with respect to the photovoltaic module based on at least information associated with the determined status. The process for measuring one or more parameters of a photovoltaic module is performed without sunlight and includes providing a light to the photovoltaic module by a light source.

According to another embodiment, a method for monitoring a photovoltaic module includes initiating a monitoring process for a photovoltaic module at a predetermined time. The photovoltaic module is connected to at least another module in a photovoltaic string as a part of a photovoltaic array. Additionally, the method includes measuring one or more parameters of the photovoltaic module by a monitoring circuit. The one or more parameters include a module current flowing through the photovoltaic module, a module voltage across the photovoltaic module, and a module temperature of the photovoltaic module. Moreover, the method includes collecting one or more measurement results of the one or more parameters, transmitting the one or more collected results using one or more radio-frequency signals, processing information associated with the one or more transmitted results, determining a module status for the photovoltaic module based on at least information associated with the one or more transmitted results, and making one or more adjustments with respect to the photovoltaic module based on at least information associated with the determined status. The process for measuring one or more parameters of a photovoltaic module is performed with sunlight but without removing the photovoltaic module from the photovoltaic array.

According to yet another embodiment, a system for monitoring a photovoltaic array includes a photovoltaic array including a plurality of photovoltaic strings. Each of the plurality of photovoltaic strings includes a plurality of photovoltaic modules, each of the plurality of photovoltaic modules includes at least one edge connector, and the edge connector includes an RFID chip embedded in the edge connector. Also, the RFID chip includes a monitoring circuit and a radio-frequency antenna. The monitoring circuit is configured to measure one or more parameters of a photovoltaic module, and the one or more parameters include a module current flowing through the photovoltaic module, a module voltage across the photovoltaic module, and a module temperature of the photovoltaic module. The radio-frequency antenna is configured to transmit one or more measurement results of the one or more measured parameters.

Many benefits are achieved by way of the present invention over conventional techniques. Certain embodiments of the present invention provide a system and method to monitor performance of individual photovoltaic modules at low cost and/or with low power consumption. For example, the system and method is applied to photovoltaic installations with a large number of photovoltaic modules.

Depending upon embodiment, one or more of these benefits may be achieved. These benefits and various additional objects, features and advantages of the present invention can be fully appreciated with reference to the detailed description and accompanying drawings that follow.

### 4. BRIEF DESCRIPTION OF THE DRAWINGS

FIG. 1A is a simplified diagram of a conventional photovoltaic array.

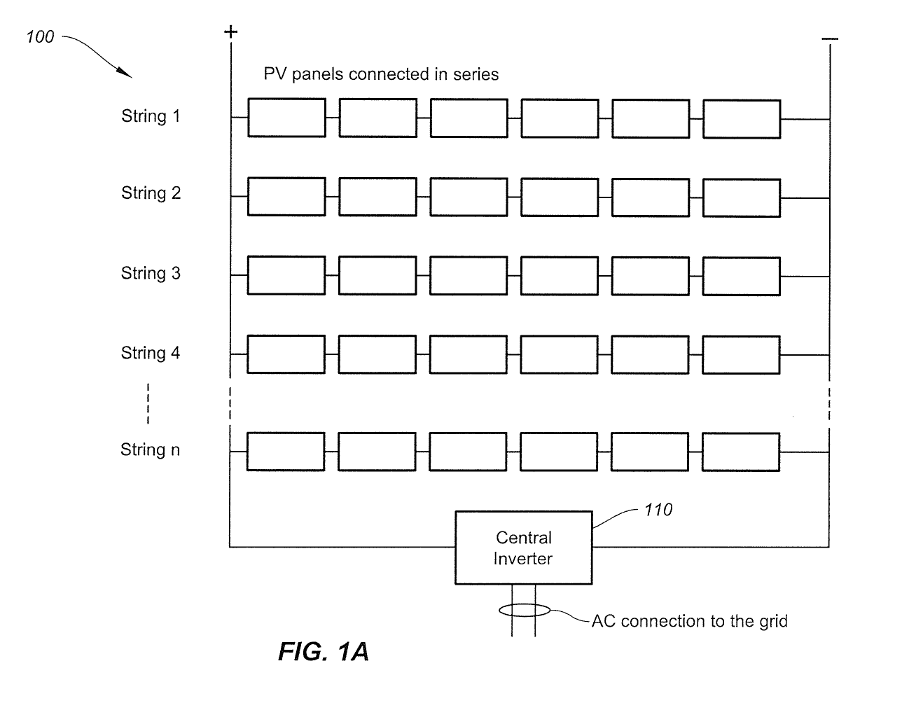

FIG. 1B is a simplified diagram of a conventional photovoltaic module.

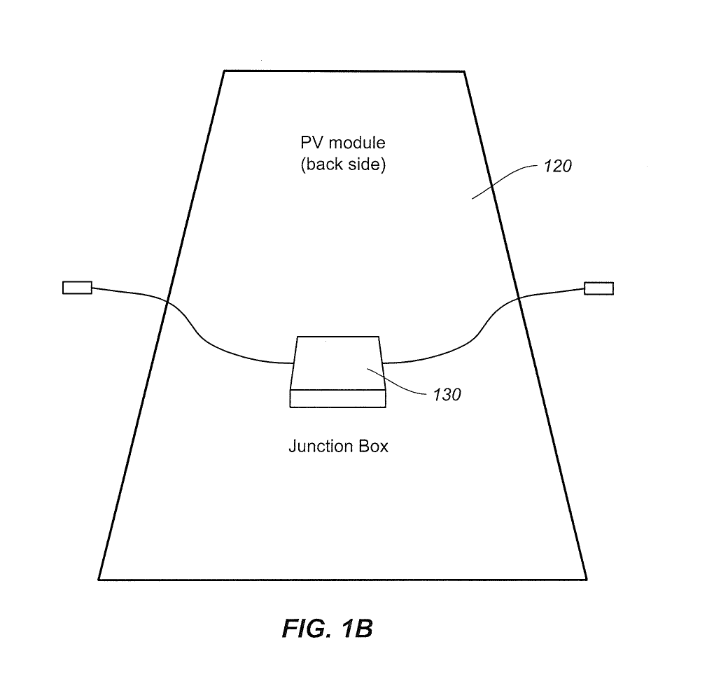

FIG. 2 is a simplified conventional current-voltage (IV) curve of a photovoltaic module.

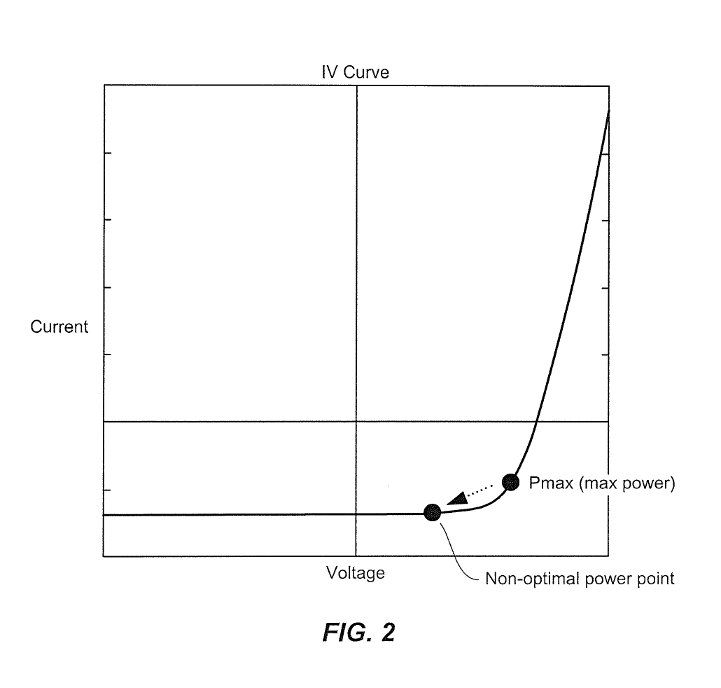

FIG. 3 is a simplified diagram showing a method for monitoring a photovoltaic module according to one embodiment of the present invention.

FIG. 4A is a simplified diagram showing a system for measuring one or more module parameters under non-operating conditions according an embodiment of the present invention.

FIG. 4B is a simplified diagram showing a system for measuring one or more module parameters under operating conditions according another embodiment of the present invention.

FIG. 5 is a simplified diagram showing a PV module with one or more molded edge connectors including one or more monitoring circuits on the backside of a PV module according to an embodiment of the present invention.

FIG. 6 is a simplified diagram showing a central transceiver in communication with one or more monitoring circuits according to an embodiment of the present invention.

FIG. 7 is a simplified diagram showing one or more transceivers in communication with one or more monitoring circuits according to another embodiment of the present invention.

FIG. 8 is a simplified diagram showing a handheld sensor in communication with one or more monitoring circuits according to another embodiment of the present invention.

### 5. DETAILED DESCRIPTION OF THE INVENTION

The present invention is directed to monitoring and diagnostics. More particularly, the invention provides systems and methods for monitoring and diagnostics of photovoltaic modules. Merely by way of example, the invention has been applied to photovoltaic systems. But it would be recognized that the invention has a much broader range of applicability.

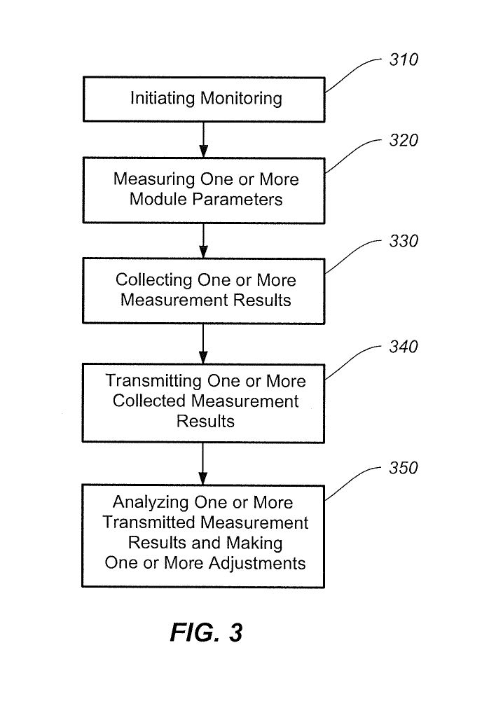

FIG. 3 is a simplified diagram showing a method for monitoring a photovoltaic module according to one embodiment of the present invention. This diagram is merely an example, which should not unduly limit the scope of the claims. One of ordinary skill in the art would recognize many variations, alternatives, and modifications. The method 300 for monitoring a photovoltaic module includes a process 310 for initiating monitoring, a process 320 for measuring one or more module parameters, a process 330 for collecting one or more measurement results of one or more measured parameters, a process 340 for transmitting one or more collected measurement results, a process 350 for analyzing one or more transmitted measurement results and making one or more adjustments in response to one or more transmitted measurement results.

At the process 310, the monitoring of one or more modules is initiated. According to one embodiment, the monitoring of one or more modules is initiated at one or more predetermined times. For example, timed self-monitoring is implemented with a timer-based circuit that initiates one or more measurements and perform instantaneous reporting or storage of data for later reporting. In another example, one advantage of timed self-monitoring is that power consumption of the monitoring circuit is reduced by putting the circuit into the standby mode between measurement events and/or data reporting events. According to another embodiment, the monitoring of one or more modules is performed continuously. For example, the monitoring circuit measures module performance continuously, and stores and/or reports the measured information continuously. According to yet another embodiment, the monitoring of one or more modules is initiated by one or more external instructions. For example, the externally triggered monitoring is implemented with a remote activation of the monitoring circuit, by, for example, an external light source that either activates sensing and/or data reporting.

At the process 320, one or more module parameters are measured for one or more modules. For example, the one or more module parameters include current, internal resistance, voltage, power, and/or temperature of a PV module. In another example, the one or more module parameters include a current as a function of voltage (e.g., an IV curve), and the dependence of current on voltage also depends on temperature.

According to one embodiment, at the process 320, the one or more module parameters are measured under non-operating conditions (e.g., at nighttime without daylight). For example, the one or more modules are individually tested (e.g., being tested one-by-one) at nighttime without being disconnected from other modules in the same PV string.

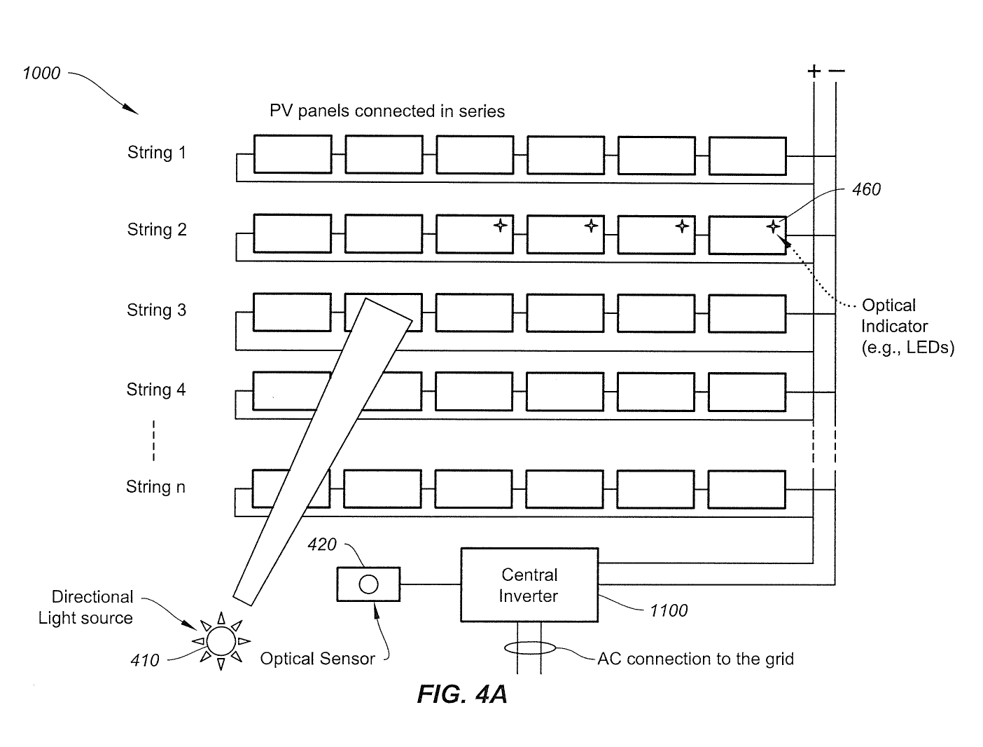

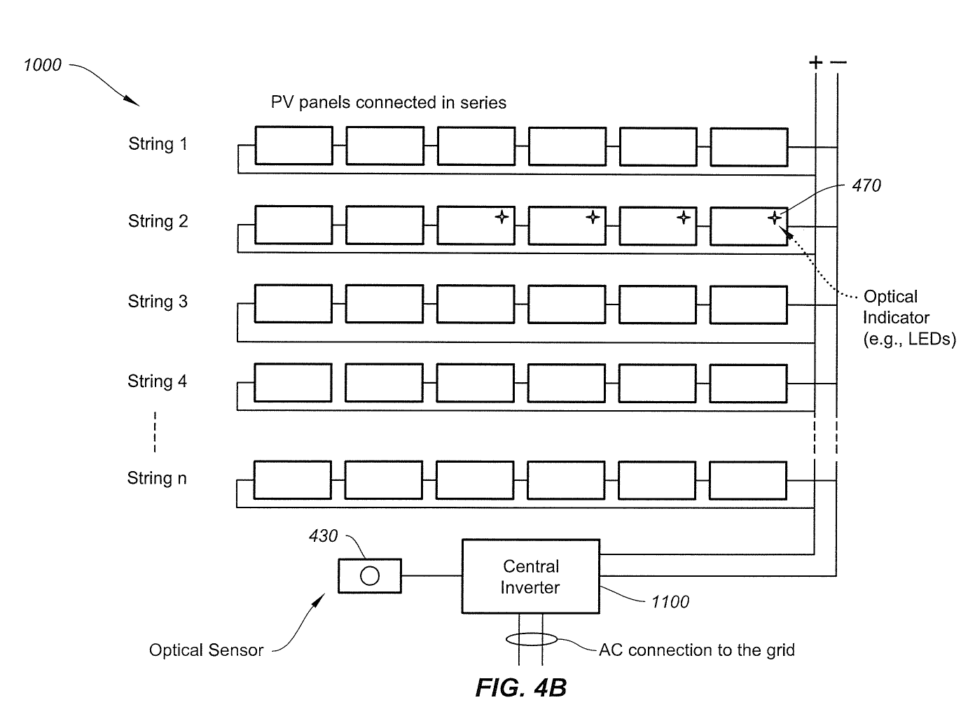

FIG. 4A is a simplified diagram showing a system for measuring one or more module parameters under non-operating conditions according an embodiment of the present invention. This diagram is merely an example, which should not unduly limit the scope of the claims. One of ordinary skill in the art would recognize many variations, alternatives, and modifications. The system includes a directional light source 410 (e.g., a laser) and an optical sensor 420 (e.g., a central optical sensor and/or a CCD camera). For example, the directional light source 410 and the optical sensor 420 are placed in similar locations.

In one embodiment, the directional light source 410 is pointed towards one photovoltaic module (e.g., one solar panel) of a photovoltaic array 1000. For example, the photovoltaic array 1000 includes strings 1, 2, 3, 4, . . . n, where n is a positive integer larger than or equal to 1. In another example, each string includes photovoltaic (PV) modules (e.g., solar panels) that are connected in series. In yet another example, the photovoltaic array 1000 is connected to a central inverter 1100, which provides an alternating current (AC) connection to the power grid.

In another embodiment, with the direction light source 410, each photovoltaic module is individually powered up in such a manner that one or more parameters (e.g., current and voltage) of the module are measured. For example, by using varying colors of the laser or other directional light source, more performance information about each individual module is obtained. In yet another embodiment, the directional light source 410 is a mobile light source, which, for example, emits light whose spectrum is the same or substantially the same as the solar spectrum. In yet another embodiment, the cost of the directional light source 410 and the optical sensor 420 is amortized over a very large number of PV modules, thus providing a cost effective and simple diagnostics system for large PV installations.

Returning to FIG. 3, for the process 320, according to another embodiment, the one or more module parameters are measured under operating conditions (e.g., at daytime with daylight).

FIG. 4B is a simplified diagram showing a system for measuring one or more module parameters under operating conditions according another embodiment of the present invention. This diagram is merely an example, which should not unduly limit the scope of the claims. One of ordinary skill in the art would recognize many variations, alternatives, and modifications. The system includes an optical sensor 430 (e.g., a central optical sensor and/or a CCD camera).

For example, all the modules in a PV string of the photovoltaic array 1000 are connected in series and all have the same current running through them, but the voltage across each individual PV module is a function of the original design specification and the degradation of the module over time. In another example, performance information of each individual PV module is obtained by measuring one or more parameters (e.g., voltage) of each PV module under operation and reporting the measured one or more parameters (e.g., voltage) for each PV module. In yet another example, the optical sensor 430 is mounted high up in the prevailing sun direction of the photovoltaic array 1000.

According to yet another embodiment, at the process 320, the one or more module parameters are measured under non-operating conditions. For example, the entire PV array, a PV string, or a PV module is taken off-line so that the array, the string, and/or the module can be tested under non-operating conditions, without physically removing individual PV modules from the PV array or the PV string. According to yet another embodiment, the one or more module parameters are measured by removing one or more individual PV modules from the PV array or the PV string and by testing the one or more removed PV modules in one or more IV testers (e.g., a tester used in module manufacturing) or with the built-in diagnostics capabilities which does not, for example, need the presence of an IV tester. In another example, the built-in diagnostics capabilities allow for simple and quick diagnostics in the field of suspect modules.

At the process 330, one or more measurement results for the one or more measured parameters are collected. In one embodiment, the one or more parameters are measured (at the process 320) and the one or more measurement results are collected (at the process 330) with radio-frequency identification (RFID) chips. For example, an intelligent RFID chip includes a built-in sensor that can detect information related to the one or more measured parameters, such as voltage, current (e.g., via a shunt), and/or temperature. In another example, an advantage for using one or more intelligent RFID chips is that the RFID chips have low power consumption (e.g., in the order of magnitude of μWatts), are small in size, and/or are inexpensive, because, for example, they are designed for high-volume consumer goods or other mobile applications.

In another embodiment, the one or more parameters are measured (at the process 320) and the one or more measurement results are collected (at the process 330) with one or more intelligent ICs (e.g., one or more ASICs). In yet another embodiment, the monitoring circuits (e.g., RFID chips and/or intelligent ICs) that are used to measure the one or more parameters (at the process 320) and to collect the one or more measurement results (at the process 330) are embedded in molded connectors.

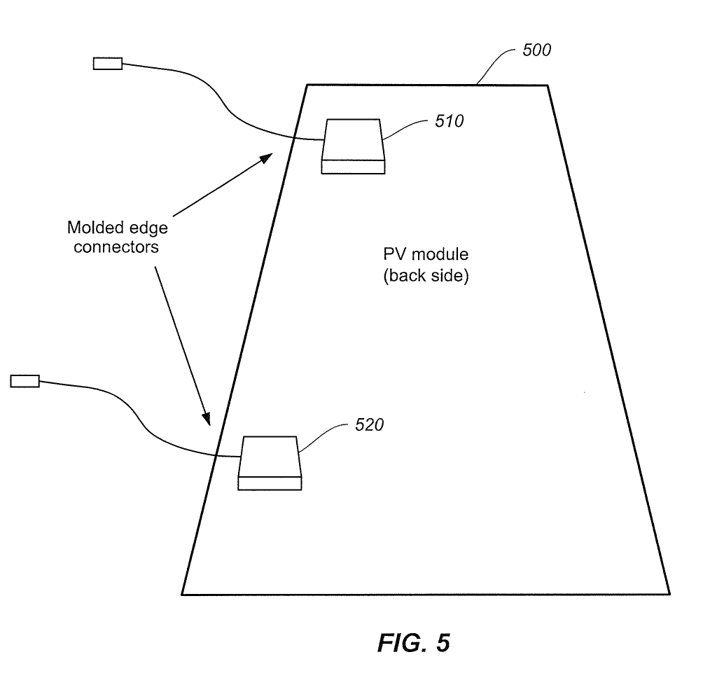

FIG. 5 is a simplified diagram showing a PV module with one or more molded edge connectors including one or more monitoring circuits on the backside of a PV module according to an embodiment of the present invention. This diagram is merely an example, which should not unduly limit the scope of the claims. One of ordinary skill in the art would recognize many variations, alternatives, and modifications. As shown, two molded edge connectors 510 and 520 are attached to the backside of a PV module 500. For example, the PV module 500 is a module of the photovoltaic array 1000. In another example, one or more monitoring circuits (e.g., one or more RFID chips and/or one or more intelligent ICs) are embedded in each of the molded connectors 510 and 520. In yet another example, into each of the molded connectors 510 and 520, one or more voltage and/or current sensing integrated circuits are embedded as parts of the one or more monitoring circuits respectively. In yet another example, the encapsulation cost of the one or more monitoring circuits is reduced or completely eliminated. In yet another example, the packaging of the one or more monitoring circuits becomes simpler and less expensive.

According to another embodiment, the monitoring circuits (e.g., RFID chips and/or intelligent ICs) are embedded in the encapsulation of the PV module itself. For example, one or more voltage and/or current sensing integrated circuits are embedded between the glass-to-glass encapsulation of the PV module itself.

At the process 340, the one or more collected measurement results for the one or more measured parameters are transmitted. For example, the one or more collected measurement results are transmitted by the transmission antennas of one or more monitoring circuits (e.g., one or more RFID chips and/or one or more intelligent ICs). In another example, the one or more transmitted measurement results are received by one or more transceivers, which further send the one or more transmitted measurement results to a data acquisition terminal.

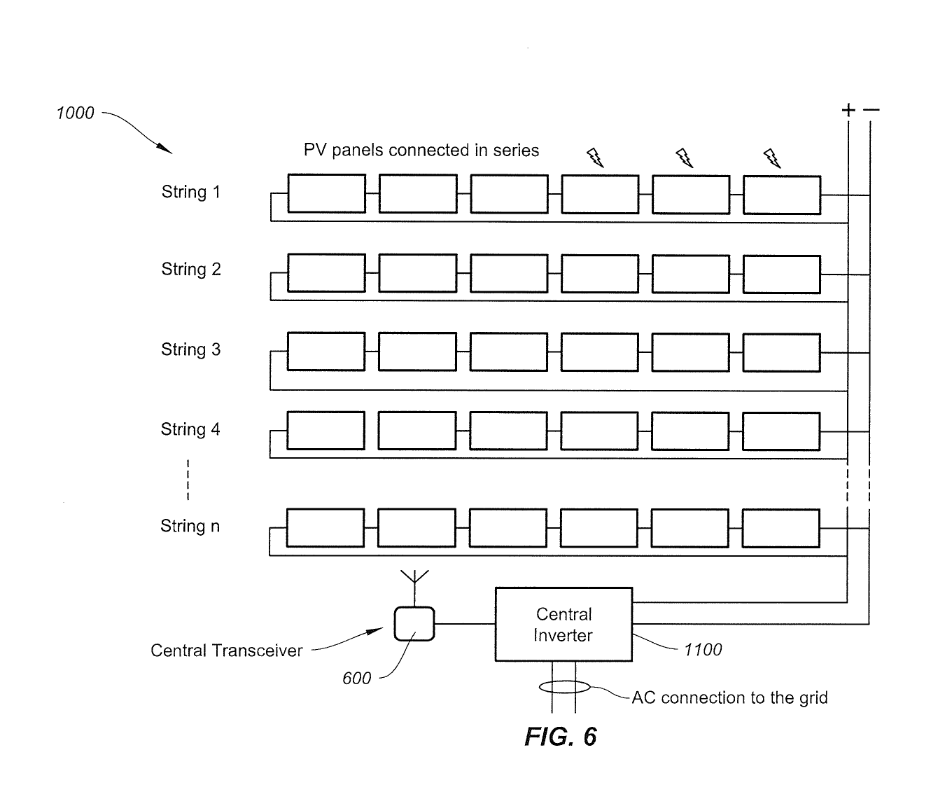

FIG. 6 is a simplified diagram showing a central transceiver in communication with one or more monitoring circuits according to an embodiment of the present invention. This diagram is merely an example, which should not unduly limit the scope of the claims. One of ordinary skill in the art would recognize many variations, alternatives, and modifications.

As shown, the one or more collected measurement results for one or more PV modules of the PV array 1000 are transmitted to the central transceiver 600 by the transmission antennas of the one or more monitoring circuits (e.g., one or more RFID chips and/or one or more intelligent ICs). For example, the central transceiver 600 is co-located with the central inverter 110. In another example, the central transceiver 600 further sends the one or more transmitted measurement results to a data acquisition terminal.

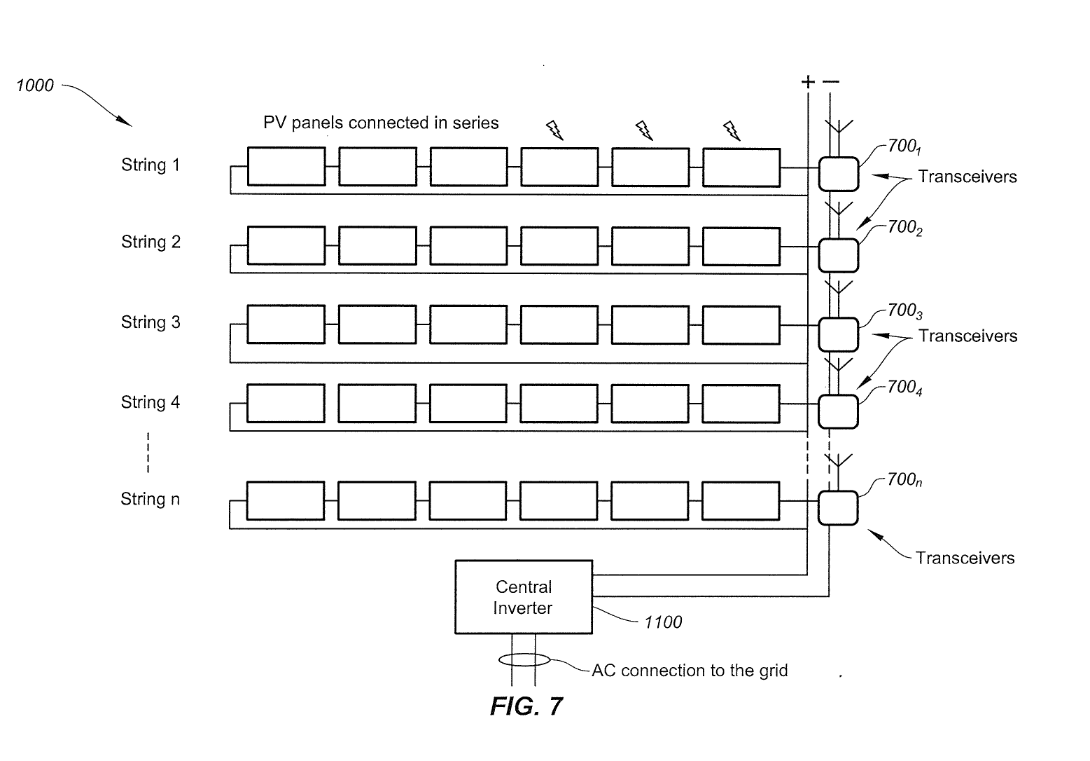

FIG. 7 is a simplified diagram showing one or more transceivers in communication with one or more monitoring circuits according to another embodiment of the present invention. This diagram is merely an example, which should not unduly limit the scope of the claims. One of ordinary skill in the art would recognize many variations, alternatives, and modifications.

As shown, the one or more collected measurement results for one or more PV modules of the PV array 1000 are transmitted to one or more transceivers 700₁, 700₂, 700₃, 700₄, . . . , 700ₙ, where n is a positive integer larger than or equal to 1. For example, the one or more transceivers 700₁, 700₂, 700₃, 700₄, . . . , 700ₙ are not co-located with the central inverter 1100. In another example, the one or more transceivers 700₁, 700₂, 700₃, 700₄, . . . , 700ₙ further send the one or more transmitted measurement results to a data acquisition terminal.

In one embodiment, the one or more transceivers 700₁, 700₂, 700₃, 700₄, . . . , 700ₙ correspond to the PV strings 1, 2, 3, 4, . . . n of the photovoltaic array 1000, respectively. For example, the one or more transceivers 700₁, 700₂, 700₃, 700₄, . . . , 700ₙ are co-located with the string inverters, the string data analysis systems, and/or the string cable junction boxes, respectively.

In another embodiment, the one or more transceivers 700₁, 700₂, 700₃, 700₄, . . . , 700ₙ receive the one or more collected measurement results for one or more PV modules that belong to their corresponding PV strings 1, 2, 3, 4, . . . n of the photovoltaic array 1000, respectively. For example, n is a positive integer larger than or equal to 1. In another example, if a PV module belongs to the PV string 1, the one or more collected measurement results for this module are received by the transceivers 700₁.

As discussed above and further emphasized here, FIG. 7 is merely an example, which should not unduly limit the scope of the claims. One of ordinary skill in the art would recognize many variations, alternatives, and modifications. For example, the one or more transceivers 700₁, 700₂, 700₃, 700₄, . . . , 700ₙ each correspond to a predetermined group of one or more PV modules of the PV array 1000. In another example, the predetermined group of one or more PV modules includes PV modules belong to different PV strings. In another example, placement of the one or more transceivers 700₁, 700₂, 700₃, 700₄, . . . , 700ₙ is determined by the maximum reaches of the RFID signals from the antennas of the one or more RFID chips (used as the one or more monitoring circuits) respectively. In yet another example, placement of the one or more transceivers 700₁, 700₂, 700₃, 700₄, . . . , 700ₙ is also determined by the size of the PV array 1000 and/or the location of the data acquisition terminal.

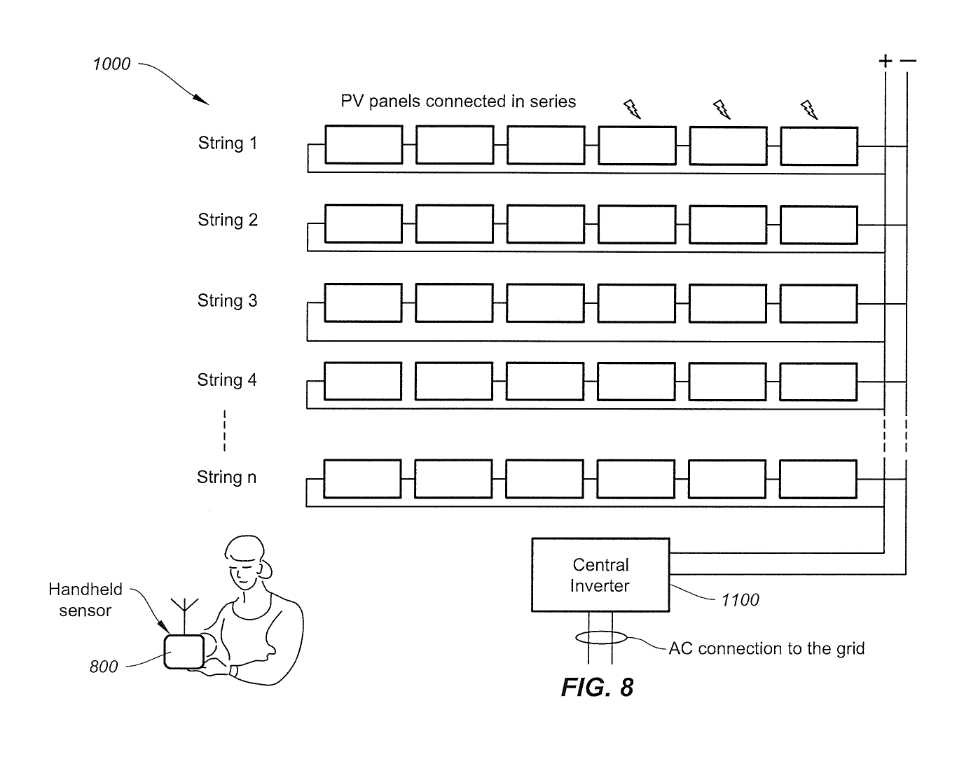

FIG. 8 is a simplified diagram showing a handheld sensor in communication with one or more monitoring circuits according to another embodiment of the present invention. This diagram is merely an example, which should not unduly limit the scope of the claims. One of ordinary skill in the art would recognize many variations, alternatives, and modifications.

As shown, the one or more collected measurement results for one or more PV modules of the PV array 1000 are transmitted to the handheld sensor 800 by the transmission antennas of the one or more monitoring circuits (e.g., one or more RFID chips and/or one or more intelligent ICs). In another example, the handheld sensor 800 further sends the one or more transmitted measurement results to a data acquisition terminal. In yet another example, more than one handheld sensor are used to receive the one or more collected measurement results for one or more PV modules of the PV array 1000.

As discussed above and further emphasized here, FIGS. 6, 7, and 8 are merely examples, which should not unduly limit the scope of the claims. One of ordinary skill in the art would recognize many variations, alternatives, and modifications. According to one embodiment, a directional light source (e.g., a laser) is added to FIGS. 6, 7, and/or 8, in order to perform measurements of one or more module parameters under non-operating conditions (e.g., at nighttime without daylight). For example, the directional light source is a mobile light source, which emits light whose spectrum is the same or substantially the same as the solar spectrum. In another example, the directional light source is pointed towards one photovoltaic module (e.g., one solar panel), so that each photovoltaic module is individually powered up in such a manner that one or more parameters (e.g., current and voltage) of the module are measured. In yet another example, by using varying colors of the laser or other directional light source, more performance information about each individual module is obtained. According to another embodiment, the handheld sensor 800 is replaced by a mobile sensor that is, for example, located on a mobile carrier together with a directional light source (e.g., a laser).

Returning to FIG. 3, for the process 340, according to another embodiment, the one or more collected measurement results for the one or more measured parameters are transmitted by light (e.g., the visible light, the infrared light, and/or the ultraviolet light).

For example, as shown in FIG. 4A, an optical indicator 460 is configured to transmit the one or more collected measurement results for the one or more measured parameters by the visible light, the infrared light, and/or the ultraviolet light, and the one or more transmitted measurement results are received by the optical sensor 420, which further sends the one or more transmitted measurement results to a data acquisition terminal. In another example, as shown in FIG. 4B, an optical indicator 470 is configured to transmit the one or more collected measurement results for the one or more measured parameters by the visible light, the infrared light, and/or the ultraviolet light, and the one or more transmitted measurement results are received by the optical sensor 430, which further sends the one or more transmitted measurement results to a data acquisition terminal.

According to certain embodiments, the optical indicators 460 and 470 each include one or more Light Emitting Diodes (LEDs), one or more Liquid Crystal Displays (LCDs), and/or one or more Organic Light Emitting Diodes (OLEDs). For example, the optical sensors 420 and 430 detect and/or record the light from the optical indicators 460 and 470 respectively. In another example, the one or more transmitted measurement results are used to determine the one or more locations of the one or more PV modules (e.g., the one or more PV module IDs) and to determine the diagnostics and/or performance information from the one or more transmitted measurement results by, for example, decoding the light from the optical indicator 460 or 470.

In one embodiment, information about the one or more collected measurement results is transmitted in an encoded way by using the one or more LEDs, the one or more LCDs, and/or the one or more OLEDs to form one or more patterns, by flashing the one or more LEDs, the one or more LCDs, and/or the one or more OLEDs, and/or by using the one or more LEDs, the one or more LCDs, and/or the one or more OLEDs of different colors according to one or more predetermined encoding schemes. In another embodiment, to reduce power consumption, the one or more LEDs, the one or more LCDs, and/or the one or more OLEDs are activated only when the one or more monitoring circuits are activated upon initiation of monitoring. In yet another embodiment, the one or more ASICs as parts of the one or more monitoring circuits are used to not only perform testing and diagnostics but also drive one or more optical indicators directly.

As discussed above and further emphasized here, FIG. 5 is merely an example, which should not unduly limit the scope of the claims. One of ordinary skill in the art would recognize many variations, alternatives, and modifications. In one embodiment, one or more LEDs, one or more LCDs, and/or one or more OLEDs are embedded in each of the molded edge connectors 510 and 520. In another embodiment, the one or more LEDs, the one or more LCDs, and/or the one or more OLEDs are embedded between the encapsulation glasses of the PV module 500. In yet another example, the one or more LEDs, the one or more LCDs, and/or the one or more OLEDs are mounted on the front side of the PV module 500 (e.g., the sun side of the PV module 500).

According to one embodiment, the one or more LEDs, the one or more LCDs, and/or the one or more OLEDs are discrete components that are mounted inside the encapsulation and/or inside the molded edge connectors of the PV module 500. According to another embodiment, the one or more LEDs, the one or more LCDs, and/or the one or more OLEDs are printed directly onto the PV module 500 as part of the PV manufacturing process.

At the process 350, the one or more transmitted measurement results are analyzed and in response, one or more adjustments are made. In one embodiment, the one or more transmitted measurement results are analyzed in order to determine the status of the one or more PV modules on a module by module basis. For example, if a PV module is diagnosed to have had a total failure or to have degraded below a given threshold, the PV module is scheduled for replacement. In another example, if a PV module is determined to need cleaning, the PV module is scheduled for cleaning.

In yet another example, the one or more transmitted measurement results are analyzed and the analysis results are used to actively compensate for the one or more degraded and/or defective modules. According to one embodiment, for a string inverter (e.g., a string DC/DC converter) and/or other apparatus with active electronics per PV string, the analysis results are used to compensate for a reduced voltage of a PV module in the PV string so that the overall string voltage is unchanged and thus does not degrade the performance of other strings. In yet another example, the analysis results are used to disconnect parts of a PV array. For example, if a PV module is sufficiently degraded, it may become optimal, from the perspective of overall power production by the PV system (including one or more PV arrays), to simply disconnect the PV string to which the degraded PV module belong from the PV array.

In yet another example, the analysis results are used to provide feedback to electricity consumers in order for them to change consumption behavior. In one embodiment, knowledge about performance of a PV array or a PV system (including one or more PV arrays) or the performance of individual components of the PV system is communicated, such as via one or more inverters, to the consumers of electricity in order for them to change their consumption behavior. For example, certain types of battery charging are preformed only when the PV system runs at peak power. In another example, the monitoring system can detect whether a portion of a PV system is losing sun radiation, such as when a cloud rolls in over a very large PV system, and can then provide a central inverter and the power grid with sufficient warning in order to plan the ramp-up of replacement power generation and/or the use of stored power.

The method 300 for monitoring a photovoltaic module has a wide range of applications. In one embodiment, the method 300 is used to monitor PV modules (e.g., solar panels) in utility-scale PV installations. For example, the utility-scale PV installations are solar farms of 1 Megawatts (MW) or larger that are connected to the electrical transmission grid directly or indirectly through electrical grid sub-stations, or are connected to lower-voltage electrical distribution grids. In another embodiment, the method 300 is used to monitor PV modules (e.g., solar panels) in large PV systems that are mounted on flat commercial building rooftops.

In yet another embodiment, the method 300 is used to monitor PV modules in large building facades. For example, the building-integrated photovoltaics (BIPV) use the façade glass to serve as both building windows and solar panels. In another example, the building-integrated photovoltaics (BIPV) include thin film panels with glass encapsulation on both sides of non-thin film panels.

In yet another embodiment, for stand-alone PV installations, the method 300 can use a built-in monitoring system with a scanner that is moved to one or more PV modules (e.g., one or more solar panels), or the one or more PV modules are moved to the scanner. For example, such a built-in monitoring system is implemented for the PV modules mounted on the roof of a car and used to diagnose at the time the car is being serviced at the service garage.

According to another embodiment, a method for monitoring a photovoltaic module includes initiating a monitoring process for a photovoltaic module at a predetermined time. The photovoltaic module is connected to at least another module in a photovoltaic string as a part of a photovoltaic array. Additionally, the method includes measuring one or more parameters of the photovoltaic module by a monitoring circuit. The one or more parameters include a module current flowing through the photovoltaic module, a module voltage across the photovoltaic module, and a module temperature of the photovoltaic module. Also, the method includes collecting one or more measurement results of the one or more parameters, transmitting the one or more collected results using one or more radio-frequency signals, processing information associated with the one or more transmitted results, determining a module status for the photovoltaic module based on at least information associated with the one or more transmitted results, and making one or more adjustments with respect to the photovoltaic module based on at least information associated with the determined status. The process for measuring one or more parameters of a photovoltaic module is performed without sunlight and includes providing a light to the photovoltaic module by a light source. For example, the method is implemented according to at least FIG. 3.

In another example, the process for collecting one or more measurement results of the one or more parameters is performed by at least one RFID chip, the RFID chip including the monitoring circuit and a radio-frequency antenna. In yet another example, the process for transmitting the one or more collected results is performed by the radio-frequency antenna. In yet another example, the process for transmitting the one or more collected results includes transmitting the one or more collected results to a plurality of inverters. The plurality of inverters corresponds to a plurality of photovoltaic strings of the photovoltaic array respectively, and the plurality of photovoltaic strings includes the photovoltaic string.

In yet another example, the process for transmitting the one or more collected results includes transmitting the one or more collected results to a mobile sensor. In yet another example, the light source is mobile and directional. In yet another example, the light is associated with a spectrum that is substantially the same as the solar spectrum. In yet another example, the process for transmitting the one or more collected results includes transmitting the one or more collected results to a sensor, and the sensor and the light source are located on a same mobile carrier. In yet another example, the process for initiating a monitoring process for a photovoltaic module is performed at a plurality of predetermined times including the predetermined time. In yet another example, the process for measuring one or more parameters of the photovoltaic module is performed repeatedly and continuously.

According to another embodiment, a method for monitoring a photovoltaic module includes initiating a monitoring process for a photovoltaic module at a predetermined time. The photovoltaic module is connected to at least another module in a photovoltaic string as a part of a photovoltaic array. Additionally, the method includes measuring one or more parameters of the photovoltaic module by a monitoring circuit. The one or more parameters include a module current flowing through the photovoltaic module, a module voltage across the photovoltaic module, and a module temperature of the photovoltaic module. Moreover, the method includes collecting one or more measurement results of the one or more parameters, transmitting the one or more collected results using one or more radio-frequency signals, processing information associated with the one or more transmitted results, determining a module status for the photovoltaic module based on at least information associated with the one or more transmitted results, and making one or more adjustments with respect to the photovoltaic module based on at least information associated with the determined status. The process for measuring one or more parameters of a photovoltaic module is performed with sunlight but without removing the photovoltaic module from the photovoltaic array. For example, the method is implemented according to at least FIG. 3.

In another example, the process for collecting one or more measurement results of the one or more parameters is performed by at least one RFID chip, and the RFID chip includes the monitoring circuit and a radio-frequency antenna. In yet another example, the process for transmitting the one or more collected results is performed by the radio-frequency antenna. In yet another example, the process for transmitting the one or more collected results includes transmitting the one or more collected results to a mobile sensor.

According to yet another embodiment, a system for monitoring a photovoltaic array includes a photovoltaic array including a plurality of photovoltaic strings. Each of the plurality of photovoltaic strings includes a plurality of photovoltaic modules, each of the plurality of photovoltaic modules includes at least one edge connector, and the edge connector includes an RFID chip embedded in the edge connector. Also, the RFID chip includes a monitoring circuit and a radio-frequency antenna. The monitoring circuit is configured to measure one or more parameters of a photovoltaic module, and the one or more parameters include a module current flowing through the photovoltaic module, a module voltage across the photovoltaic module, and a module temperature of the photovoltaic module. The radio-frequency antenna is configured to transmit one or more measurement results of the one or more measured parameters. For example, the system is implemented according to at least FIG. 4A, FIG. 4B, FIG. 5, FIG. 6, FIG. 7, and/or FIG. 8.

In another example, the system also includes a light source configured to provide a light to the photovoltaic module. In yet another example, the light source is mobile and directional. In yet another example, the light is associated with a spectrum that is substantially the same as the solar spectrum. In yet another example, the radio-frequency antenna is further configured to transmit the one or more measurement results of the one or more measured parameters to a plurality of inverters, and the plurality of inverters corresponding to the plurality of photovoltaic strings of the photovoltaic array respectively. In yet another example, the radio-frequency antenna is further configured to transmit the one or more measurement results of the one or more measured parameters to a mobile sensor. In yet another example, the mobile sensor and the light source are located on a same mobile carrier.

Although specific embodiments of the present invention have been described, it will be understood by those of skill in the art that there are other embodiments that are equivalent to the described embodiments. Accordingly, it is to be understood that the invention is not to be limited by the specific illustrated embodiments, but only by the scope of the appended claims.

What is claimed is:

1. A method for monitoring a photovoltaic module, the method comprising:
initiating a monitoring process for a photovoltaic module at a predetermined time, the photovoltaic module being connected to at least another module in a photovoltaic string as a part of a photovoltaic array;
measuring one or more parameters of the photovoltaic module by a monitoring circuit, the one or more parameters including a module current flowing through the photovoltaic module, a module voltage across the photovoltaic module, and a module temperature of the photovoltaic module;
collecting one or more measurement results of the one or more parameters;
transmitting the one or more collected results using one or more radio-frequency signals;
processing information associated with the one or more transmitted results;
determining a module status for the photovoltaic module based on at least information associated with the one or more transmitted results;
making one or more adjustments with respect to the photovoltaic module based on at least information associated with the determined status;
wherein the process for measuring one or more parameters of a photovoltaic module is performed without sunlight and includes providing a light to the photovoltaic module by a light source.

2. The method of claim 1 wherein the process for collecting one or more measurement results of the one or more parameters is performed by at least one RFID chip, the RFID chip including the monitoring circuit and a radio-frequency antenna.

3. The method of claim 2 wherein the process for transmitting the one or more collected results is performed by the radio-frequency antenna.

4. The method of claim 1 wherein the process for transmitting the one or more collected results includes transmitting the one or more collected results to a plurality of inverters, the plurality of inverters corresponding to a plurality of photovoltaic strings of the photovoltaic array respectively, the plurality of photovoltaic strings including the photovoltaic string.

5. The method of claim 1 wherein the process for transmitting the one or more collected results includes transmitting the one or more collected results to a mobile sensor.

6. The method of claim 1 wherein the light source is mobile and directional.

7. The method of claim 1 wherein the light is associated with a spectrum that is substantially the same as the solar spectrum.

8. The method of claim 1 wherein the process for transmitting the one or more collected results includes transmitting the one or more collected results to a sensor, the sensor and the light source being located on a same mobile carrier.

9. The method of claim 1 wherein the process for initiating a monitoring process for a photovoltaic module is performed at a plurality of predetermined times including the predetermined time.

10. The method of claim 1 wherein the process for measuring one or more parameters of the photovoltaic module is performed repeatedly and continuously.

11. A method for monitoring a photovoltaic module, the method comprising:
initiating a monitoring process for a photovoltaic module at a predetermined time, the photovoltaic module being connected to at least another module in a photovoltaic string as a part of a photovoltaic array;
measuring one or more parameters of the photovoltaic module by a monitoring circuit, the one or more parameters including a module current flowing through the photovoltaic module, a module voltage across the photovoltaic module, and a module temperature of the photovoltaic module;
collecting one or more measurement results of the one or more parameters;
transmitting the one or more collected results using one or more radio-frequency signals;
processing information associated with the one or more transmitted results;
determining a module status for the photovoltaic module based on at least information associated with the one or more transmitted results;
making one or more adjustments with respect to the photovoltaic module based on at least information associated with the determined status;
wherein the process for measuring one or more parameters of a photovoltaic module is performed with sunlight but without removing the photovoltaic module from the photovoltaic array.

12. The method of claim 11 wherein the process for collecting one or more measurement results of the one or more parameters is performed by at least one RFID chip, the RFID chip including the monitoring circuit and a radio-frequency antenna.

13. The method of claim 12 wherein the process for transmitting the one or more collected results is performed by the radio-frequency antenna.

14. The method of claim 11 wherein the process for transmitting the one or more collected results includes transmitting the one or more collected results to a mobile sensor.

15. A system for monitoring a photovoltaic array, the system comprising:
a photovoltaic array including a plurality of photovoltaic strings;
wherein:
each of the plurality of photovoltaic strings includes a plurality of photovoltaic modules;
each of the plurality of photovoltaic modules includes at least one edge connector; and
the edge connector includes an RFID chip embedded in the edge connector;
wherein:
the RFID chip includes a monitoring circuit and a radio-frequency antenna;
the monitoring circuit is configured to measure one or more parameters of a photovoltaic module, the one or more parameters including a module current flowing through the photovoltaic module, a module voltage across the photovoltaic module, and a module temperature of the photovoltaic module; and
the radio-frequency antenna is configured to transmit one or more measurement results of the one or more measured parameters.

16. The system of claim 15, and further comprising a light source configured to provide a light to the photovoltaic module.

17. The system of claim 16 wherein the light source is mobile and directional.

18. The system of claim 16 wherein the light is associated with a spectrum that is substantially the same as the solar spectrum.

19. The system of claim 15 wherein the radio-frequency antenna is further configured to transmit the one or more measurement results of the one or more measured parameters to a plurality of inverters, the plurality of inverters corresponding to the plurality of photovoltaic strings of the photovoltaic array respectively.

20. The system of claim 15 wherein the radio-frequency antenna is further configured to transmit the one or more measurement results of the one or more measured parameters to a mobile sensor.

21. The system of claim 20 wherein the mobile sensor and the light source are located on a same mobile carrier.
